(19) United States
(12) Patent Application Publication
(10) Pub. No.: US 2018/0188564 A1
(43) Pub. Date: Jul. 5, 2018

(54) DISPLAY PANEL AND METHOD OF MANUFACTURING THE SAME, DISPLAY DEVICE AND METHOD OF MANUFACTURING THE SAME

(71) Applicants: BOE TECHNOLOGY GROUP CO., LTD., Beijing (CN); HEFEI XINSHENG OPTOELECTRONICS TECHNOLOGY CO., LTD., Hefei, Anhui (CN)

(72) Inventors: Liangliang JIANG, Beijing (CN); Lei GUO, Beijing (CN); Rongjun YOON, Beijing (CN)

(21) Appl. No.: 15/531,489

(22) PCT Filed: Jan. 6, 2017
(86) PCT No.: PCT/CN2017/070383

§ 371 Date: May 30, 2017

(30) Foreign Application Priority Data
Apr. 15, 2016 (CN) 201610236519.9

(51) Int. Cl. G02F 1/1339; G02F 1/1341; G02F 1/136; H01L 27/12

(52) U.S. Cl. CPC G02F 1/1339; H01L 27/1214; G02F 1/136; G02F 1/1341

(57) ABSTRACT

The present disclosure relates to a display panel and a method of manufacturing the same, and a display device and a method of manufacturing the same. The display panel has a display region and a non-display region on the periphery of the display region, in which non-display region there are provided a seal surrounding the display region and a sealing element located outside the seal, wherein the sealing element includes a first layer, wherein the first layer includes a thermosetting material.

### CROSS REFERENCE TO RELATED APPLICATIONS

This patent application is a National Stage Entry of PCT/CN2017/070383 filed on Jan. 6, 2017, which claims the benefit and priority of Chinese Patent Application No. 201610236519.9 filed on Apr. 15, 2016, the disclosures of which are incorporated by reference herein in their entirety as part of the present application.

### BACKGROUND

The present disclosure relates to the field of display technology, and in particular, to a display panel and a method of manufacturing the same, and a display device and a method of manufacturing the same.

At present in the field of liquid crystal display panels, liquid crystal display panel is generally formed by a CF (color film) substrate, a TFT (i.e., Thin Film Transistor) substrate, and an LC (Liquid Crystal) layer filled therebetween. In order to seal the liquid crystal in the display panel to prevent the liquid crystal leakage and fix the positions of the upper and lower substrates, the industry can only coat a layer of seal in the edge of the panel to play the role of sealing the liquid crystal and fixing the upper and lower substrates.

However, the liquid crystal display panel is often subject to high temperature, high humidity, high pressure, and other working environment during the transport, loading and unloading and use thereof, so its reliability performance ability becomes an important factor to restrict product quality, cost and price. However, the seal itself might be eroded by the external environment under severe conditions such as high temperature (H), high humidity (W), high pressure (P), and the interface between the seal and the PS layer (or OC layer) of the CF substrate surface and the interface between the seal and the PVX layer of the TFT substrate are not uniform with poor adhesion and other deficiencies, prone to water vapor or gas intrusion, thus damaging the sealability of the seal and the stability in the liquid crystal panel.

### BRIEF DESCRIPTION

An embodiment of the present disclosure provides a display panel and a method of manufacturing the same, and a display device and a method of manufacturing the same, which can at least partially alleviate the problems in the prior art that the narrow bezel cannot be realized, that the complete sealing cannot be achieved, and that there are high requirements for the process.

The present disclosure provides a display panel.

A first aspect of the present disclosure provides a display panel having a display region and a non-display region on the periphery of the display region, wherein a seal surrounding the display region and a sealing element located outside the seal are provided in the non-display region, and wherein the sealing element includes a first layer, and the first layer includes a thermosetting material.

In one embodiment, the thermosetting material includes a thermosetting organic resin.

In one embodiment, the thermosetting organic resin includes Polymethyl Methacrylate (PMMA).

In one embodiment, the sealing element further includes a second layer under the first layer, the second layer including a pressure sensitive adhesive.

In one embodiment, the pressure sensitive adhesive includes a styrene type thermoplastic elastomer.

In one embodiment, the styrene type thermoplastic elastomer includes SIS, SBS, SEBS, and epoxidized SBS.

In one embodiment, the display panel includes a first substrate and a second substrate arranged opposite to each other, the seal and the sealing element being located between the bottom surface of the first substrate and the top surface of the second substrate to seal the space between the first substrate and the second substrate.

In one embodiment, the top of the second substrate has a concavo-convex shape at a position corresponding to the second layer.

Alternatively, the first substrate is a color film substrate, the second substrate is a thin film transistor (TFT) substrate, a spacer is provided between the color film substrate and the TFT substrate, and the spacer is located inside the seal.

The present disclosure also provides a display device.

A second aspect of the present disclosure provides a display device including the above-described display panel.

The present disclosure further provides a method for manufacturing a display panel.

A third aspect of the present disclosure provides a method for manufacturing a display panel, including providing a first substrate and a second substrate, providing a seal on the first substrate, the seal being located on the periphery of a display region of the display panel, wherein the method further includes providing a first layer on the first substrate, the first layer being located outside the seal and including a thermosetting material, joining the first substrate and with second substrate to form a cell.

In one embodiment, the thermosetting material includes a thermosetting organic resin.

In one embodiment, the thermosetting organic resin includes Polymethyl Methacrylate (PMMA).

In one embodiment, the method further includes providing a second layer at a position on the second substrate aligned with the first layer, wherein the second layer includes a pressure sensitive adhesive.

In one embodiment, the pressure sensitive adhesive includes a styrene type thermoplastic elastomer.

In one embodiment, the styrene type thermoplastic elastomer includes SIS, SBS, SEBS, and epoxidized SBS.

In one embodiment, the method further includes configuring a top of the second substrate at a position corresponding to the second layer to have a convexo-concave shape.

Alternatively, the first substrate is a color film substrate, and the second substrate is a TFT substrate, the method further includes providing a spacer on the color film substrate, the spacer being located inside the seal, providing liquid crystal on the TFT substrate, and joining the first substrate with the second substrate to form a cell.

The present disclosure further providing a method of manufacturing a display device.

A fourth aspect of the present disclosure provides a method of manufacturing a display device including a method of manufacturing the display panel as described above.

The display panel and the method of manufacturing the same, the display device and the method of manufacturing the same provided in the embodiments of the present disclosure, are provided with the seal surrounding the display region in the non-display region and the sealing element located outside the seal, wherein the sealing element includes a first layer, wherein the first layer includes a thermosetting material.

### BRIEF DESCRIPTION OF THE DRAWINGS

In order to more clearly illustrate the technical solutions of the embodiments of the present disclosure, the drawings of the embodiments will be briefly described below. It should be understood that the drawings described below merely relate to some embodiments of the present disclosure rather than limiting the present disclosure, in which:

FIG. 1 is a schematic view of a color film substrate according to one embodiment of the present disclosure;

FIG. 2 is a schematic view of a manufacturing process according to one embodiment of the present disclosure;

FIGS. 3A and 3B are schematic views showing the process of combing the CF and TFT substrates to form a cell according to one embodiment of the present disclosure; and

FIGS. 4A and 4B are schematic views showing the process of combing the CF and TFT substrates to form a cell according to another embodiment of the present disclosure.

### DETAILED DESCRIPTION

To make the technical solutions and advantages of the present disclosure more clear, the technical solutions of the embodiments of the present disclosure will be clearly and completely described below in conjunction with the drawings. Obviously, the embodiments described are part of embodiments of the present disclosure, instead of all the embodiments. Based on the described embodiments of the present disclosure, all other embodiments obtained by those skilled in the art without creative work also fall within the scope of protection sought for by the present disclosure.

Unless otherwise defined, technical terms or scientific terms used herein should have common meaning understood by those of ordinary skill in the art to which the present disclosure belongs. The words “first”, “second” and the like used in the specification and claims of the present patent application do not indicate any order, quantity or importance, but are merely used to distinguish different composition parts. When elements of the present disclosure and their embodiments are introduced, the articles “a”, “an”, “this” and “the” are intended to indicate the presence of one or more elements. The terms “comprising”, “including”, “containing” and “having” are intended to be inclusive and indicate that there may be additional elements other than the listed elements.

For the purpose of the following description, the terms “upper”, “lower”, “left”, “right”, “vertical”, “horizontal”, “top”, “bottom” and derivatives thereof, shall involve the present disclosure as in the denoted direction in the drawings. The terms “on”, “on top of . . . ”, “located on . . . ”, or “located on top of . . . ” mean the presence of a first element such as a first structure on a second element such as a second structure, wherein an intermediate element such as an interface structure may be present between the first element and the second element. The term “contact” means connecting the first element such as a first structure with the second element such as a second structure, while other elements may be or may be not present at the interface between the two elements.

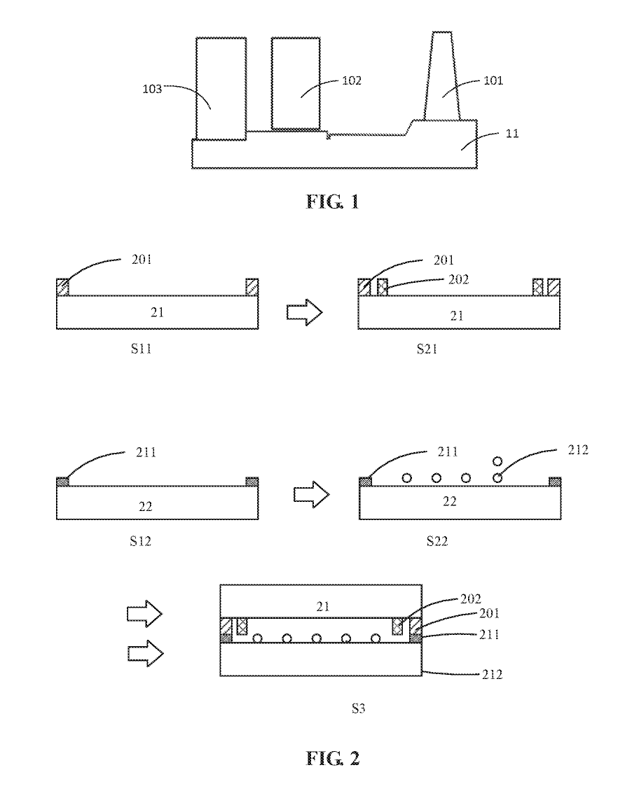

FIG. 1 is a schematic view of a first substrate according to an embodiment of the present disclosure. As shown in FIG. 1, in the present embodiment, in addition to a seal 102 located on the periphery of a display region of a display panel and a spacer 101 located inside the seal on a first substrate 11, a blocking layer 103 (also referred to as a “first layer”) is further disposed outside the seal and the first layer 103 includes a thermosetting material.

The thermosetting material of the first layer may be an organic resin. The organic resin layer may employ Polymethyl Methacrylate (PMMA) and its composite with epoxy. Polymethyl Methacrylate (PMMA) has high hardness, high transparency, good thermal stability, good weatherability and other properties, and because it can implement fine pattern through the mask exposure lithography in the process, it can be used as an ideal blocking protection layer, and can improve the reliability effect of the panel in the external environment.

In one embodiment, an organic resin layer may be prepared on the periphery of the region coated and sealed with the seal through a coater coating, a mask exposure, and a development process.

FIG. 2 is a schematic view of a manufacturing process according to one embodiment of the present disclosure, wherein the exemplary description is given taking the first substrate being a CF substrate and the second substrate being a TFT substrate as an example. As shown in FIG. 2, the manufacturing process according to one embodiment of the present disclosure includes S11, providing a blocking layer (first layer) 201 on the CF substrate 21, S21, providing a seal 202 on the CF substrate, S12, providing a second layer 211 on the TFT substrate 22 at a position where is aligned with the first layer 201 on the CF substrate, the second layer including a pressure sensitive adhesive (PSA), S22, providing liquid crystal 212 on the TFT substrate, and S3, joining the CF substrate with the TFT substrate to form a cell.

The seal is located on the periphery of the display region of the display panel and the first layer is located outside the seal. The seal and the pressure sensitive adhesive can be provided in a coating way, and the liquid crystal can be provided in a dropping way. The alignment and combination of the first substrate and the second substrate may be carried out under a vacuum condition, and may of course be carried out under other conditions as long as no bubbles are present between the two substrates after being adhered together.

In the present embodiment, a second layer including a pressure sensitive adhesive is used, and the first layer and the second layer together form a sealing element. Pressure sensitive adhesives are a kind of adhesives sensitive to pressure, mainly used for the preparation of pressure sensitive tapes. Through the pressure sensitive adhesive, the organic resin cured and stabilized can be connected with the substrate to form a more stable sealing structure, to remove possible gaps, and to improve the reliability in high humidity, high heat, and high pressure.

In one embodiment, the pressure sensitive adhesive includes a styrene type thermoplastic elastomer. Specifically, the styrene type thermoplastic elastomer may include SIS (Styrene-Isoprene-Styrene), SBS (Styrene-Butadiene-Styrene), SEBS (Styrene-Ethylene-Butylene-Styrene), and epoxidized SBS.

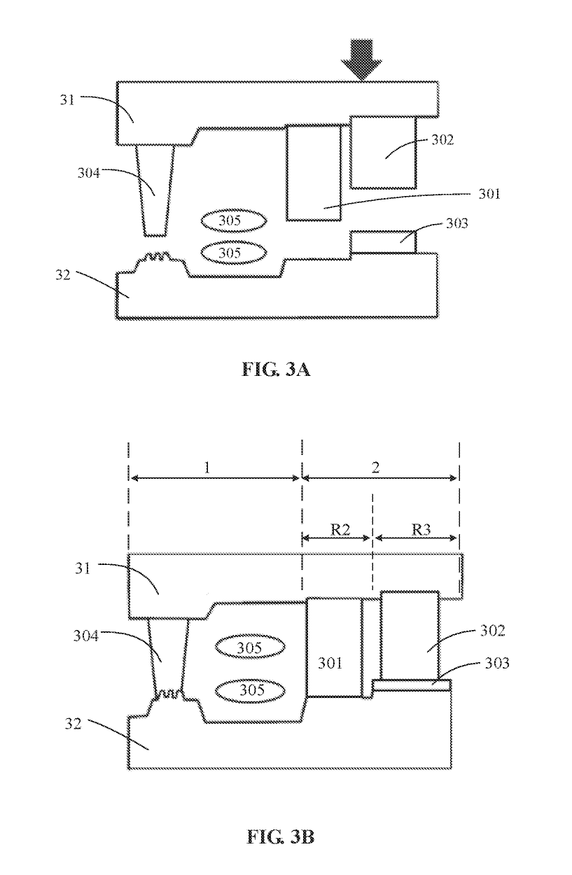

FIGS. 3A and 3B are schematic views showing the process of combing the CF with TFT substrates to form a cell according to one embodiment of the present disclosure.

FIG. 3A is a schematic view before the combination of a first substrate and a second substrate to form a cell according to one embodiment of the present disclosure. As shown in FIG. 3A, the first substrate 31 is a color film substrate on which a seal 301 is provided. The seal 301 is located on the periphery of the display region of the display panel. A first layer 302 is further disposed on the first substrate 31, wherein the first layer 302 is located outside the seal 301 and includes a thermosetting material. The second substrate 32 is a thin film transistor (TFT) substrate, and a second layer 303 is provided at a position on the second substrate aligned with the first layer 302, wherein the second layer 303 includes a pressure sensitive adhesive.

Wherein, the flat lower surface of the spacer 304 in FIG. 3A is only exemplary, and the lower surface may be flat or non-flat. Liquid crystal 305 may be further provided between the color film substrate 31 and the TFT substrate 32.

FIG. 3B is a schematic view after the combination of a first substrate and a second substrate to form a cell according to one embodiment of the present disclosure. As shown in FIG. 3B, the display panel according to the present embodiment includes a first substrate 31 and a second substrate 32 provided opposite to each other. The display panel has a display region 1 and a non-display region 2 (sealing region R2 and blocking region R3) on the periphery of the display region. In the display region, a seal 301 surrounding the display region and a sealing element located outside the seal are provided. The sealing element includes a first layer 302, the first layer including a thermosetting material. The sealing element further includes a second layer 303, the second layer including a pressure sensitive adhesive. As shown in FIG. 3B, the seal and the sealing element are located between the bottom surface of the first substrate and the top surface of the second substrate to seal the space between the first substrate and the second substrate.

A spacer 304 may be further provided between the color film substrate 31 and the TFT substrate 32. The spacer 304 is located inside the seal 301, and liquid crystal 305 is provided between the spacer 304 and the seal 301.

In particular, the color film substrate 31 may include a first base, a black matrix, a color blocking layer, and a planarization layer. The TFT substrate 32 may include a second base, a gate, a passivation layer, an insulating layer, and a source/drain. It should be noted that the structures of the first substrate and the second substrate are not limited to the structure shown in the drawings, but may include any other suitable structure.

In one embodiment, the top (e.g., passivation layer or source/drain layer) of the second substrate may have a convexo-concave shape at a position corresponding to the second layer to increase its contact area with the sealing element, thereby increasing the bonding force and enhancing the cohesive force. This will be further described below with reference to FIG. 7.

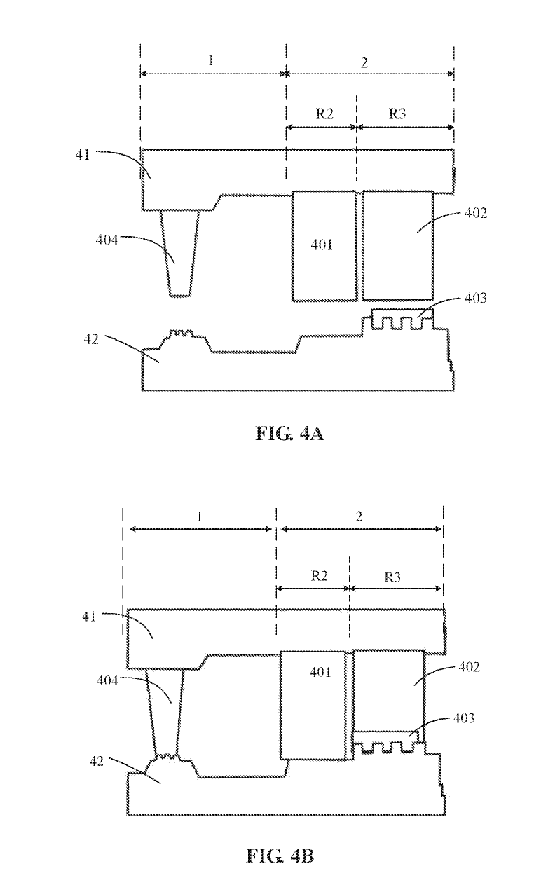

FIGS. 4A and 4B are schematic views showing the process of combing the CF with TFT substrates to form a cell according to another embodiment of the present disclosure.

FIG. 4A is a schematic view before the combination of a first substrate and a second substrate to form a cell according to one embodiment of the present disclosure. As shown in FIG. 4A, the first substrate 41 is a color film substrate on which a seal 401 is provided, and the seal 401 is located on the periphery of the display region of the display panel. A first layer 402 is also provided on the first substrate 41, and the first layer 402 is located outside the seal 401 and includes a thermosetting material. The second substrate 42 is a thin film transistor (TFT) substrate, and a second layer 403 is provided at a position of the second substrate aligned with the first layer 402, the second layer 403 including a pressure sensitive adhesive.

Wherein, the flat lower surface of the spacer 405 in FIG. 4A is schematic only, and the lower surface of the spacer 405 may be flat or non-flat.

FIG. 4B is a schematic view after the combination of a first substrate and a second substrate to form a cell according to one embodiment of the present disclosure. As shown in FIG. 4B, the display panel according to the present embodiment includes a first substrate 41 and a second substrate 42 arranged opposite to each other. Similarly as shown in FIGS. 3A and 3B, the display panel has a display region 1 and a non-display region 2 (sealing region R2 and blocking region R3) on the periphery of the display region. A seal 401 surrounding the display region and a sealing element located outside the seal are provided in the display region. The sealing element includes a first layer 402, wherein the first layer includes a thermosetting material. The sealing element further includes a second layer 403, the second layer including a pressure sensitive adhesive. As shown in FIG. 4B, the seal and the sealing element are located between the bottom surface of the first substrate and the top surface of the second substrate to seal the space between the first substrate and the second substrate.

A spacer 404 may be further provided between the color film substrate 41 and the TFT substrate 42. The spacer 404 is located inside the seal 401, and liquid crystal (not shown) is provided between the spacer 405 and the seal 401.

In particular, the color film substrate 41 may include a first base, a black matrix, a color blocking layer, and a planarization layer. The TFT substrate 42 may include a second base, a gate, a passivation layer, an insulating layer, and a source/drain. It should be noted that the structures of the first substrate and the second substrate are not limited to the structure shown in the drawings, but may be any other suitable structure.

It should be noted that in the present disclosure, the first substrate being a color film substrate and the second substrate being a TFT substrate are merely exemplary and are not intended to limit the present disclosure. Further, a first layer containing a thermosetting material may be provided on the TFT layer during the manufacturing process according to needs, and a second layer containing a pressure sensitive adhesive may be provided on the color film substrate.

The present disclosure provides a technical solution to improve the reliability of liquid crystal display panel seal. A first layer containing a thermosetting material may be provided on the first substrate side by exposure or the like, and a second layer containing a pressure sensitive adhesive may be provided on the second substrate side corresponding to the first layer. Also, in the process of alignment and combination (e.g., vacuum alignment and combination), the two substrates are connected by the seal, and the first layers between the connected substrates are sealed by a pressure sensitive adhesive. Through the solution of the present disclosure, a real complete sealing can be realized, to overcome shortcomings in the traditional method like wide bezel, high process requirements, and insufficient sealing effects, greatly enhancing product yield rate and reliability.

The display device in the present embodiment may be any product or component having a display function such as a mobile phone, a tablet computer, a television set, a notebook computer, a digital photo frame, a navigator, or the like.

Some particular embodiments have been described, and these embodiments are presented by way of example only and are not intended to limit the scope of the present disclosure. In fact, the novel embodiments described herein may be embodied in various other forms. Furthermore, various omissions, substitutions and alterations in the form of embodiments described herein may be made without departing from the spirit of the disclosure. The appended claims and their equivalents are intended to cover such forms or modifications which fall within the spirit and scope of the present disclosure.

1. A display panel comprising:
a display region; and
a non-display region on the periphery of the display region, wherein a seal surrounding the display region and a sealing element located outside the seal are provided in the non-display region, and wherein the sealing element comprises a first layer comprising a thermosetting material.

2. The display panel according to claim 1, wherein the thermosetting material comprises a thermosetting organic resin.

3. The display panel according to claim 2, wherein the thermosetting organic resin comprises Polymethyl Methacrylate (PMMA).

4. The display panel according to claim 1, wherein the sealing element further comprises a second layer under the first layer, the second layer comprising a pressure sensitive adhesive.

5. The display panel according to claim 4, wherein the pressure sensitive adhesive comprises a styrene type thermoplastic elastomer.

6. The display panel according to claim 5, wherein the styrene type thermoplastic elastomer comprises SIS, SBS, SEES, and epoxidized SBS.

7. The display panel according to claim 4, wherein the display panel comprises a first substrate and a second substrate arranged opposite to each other, and wherein the seal and the sealing element are located between the bottom surface of the first substrate and the top surface of the second substrate to seal the space between the first substrate and the second substrate.

8. The display panel according to claim 7, wherein the top of the second substrate has a concavo-convex shape at a position corresponding to the second layer.

9. The display panel according to claim 7, wherein the first substrate is a color film substrate, the second substrate is a thin film transistor (TFT) substrate, a spacer is provided between the color film substrate and the TFT substrate, and the spacer is located inside the seal.

10. A display device comprising the display panel according to claim 1.

11. A method for manufacturing a display panel comprising:
providing a first substrate and a second substrate;
disposing a seal on the first substrate, the seal being located on the periphery of a display region of the display panel;
disposing a first layer on the first substrate, wherein the first layer is located outside the seal and comprises a thermosetting material; and
joining the first substrate with the second substrate to form a cell.

12. The method according to claim 11, wherein the thermosetting material comprises a thermosetting organic resin.

13. The method according to claim 12, wherein the thermosetting organic resin comprises Polymethyl Methacrylate (PMMA).

14. The method according to claim 13, wherein the method further comprises disposing a second layer at a position on the second substrate where is aligned with the first layer, and wherein the second layer comprises a pressure sensitive adhesive.

15. The method according to claim 11, wherein the pressure sensitive adhesive comprises a styrene type thermoplastic elastomer.

16. The method according to claim 15, wherein the styrene type thermoplastic elastomer comprises SIS, SBS, SEBS, and epoxidized SBS.

17. The method according to claim 14, wherein the method further comprises configuring a top of the second substrate at a position corresponding to the second layer to have a convexo-concave shape.

18. The method according to claim 11, wherein the first substrate is a color film substrate, and wherein the second substrate is a TFT substrate, the method further comprising:
providing a spacer on the color film substrate, the spacer being located inside the seal;
disposing liquid crystal on the TFT substrate; and
joining the first color film with the second TFT to form a cell.

19. A method for manufacturing a display device, comprising the method for manufacturing a display panel according to claim 11.

20. The display device according to claim 10, wherein the sealing element further comprises a second layer under the first layer, and wherein the second layer comprises a pressure sensitive adhesive.
